(19) United States
(12) Patent Application Publication
(10) Pub. No.: US 2025/0015235 A1
(43) Pub. Date: Jan. 9, 2025

(54) METHOD FOR ATTACHING MICRO LEDS TO DISPLAY BY USING FLUID AS SOFT LANDING MEDIUM FOR MICRO LEDS

(71) Applicant: LABENT, INC, Seongnam-si, Gyeonggi-do (KR)

(72) Inventors: Jong Hwa LEE, Seoul (KR); Heon-Min LEE, Yongin-si, Gyeonggi-do (KR); Keun-Ho LEE, Suwon-si, Gyeonggi-do (KR)

(21) Appl. No.: 18/713,625

(22) PCT Filed: Oct. 21, 2022
(86) PCT No.: PCT/KR2022/016150

§ 371 Date: May 24, 2024

(30) Foreign Application Priority Data
Dec. 14, 2021 (KR) 10-2021-0178723
Aug. 4, 2022 (KR) 10-2022-0097259

(51) Int. Cl. H01L 33/48; H01L 25/075

(52) U.S. Cl. CPC H01L 33/486; H01L 25/0753

(57) ABSTRACT

The present invention relates to a method for attaching micro LEDs at preset mounting positions on a target substrate, comprising the steps of: (a1) disposing, at the bottom of a filled fluid, a target substrate assembly to which micro LEDs are to be attached, and preparing a water tank in which the plurality of micro LEDs float in the fluid or on the surface of the fluid on the target substrate assembly, (b1) lowering the level of the fluid in the water tank so as to lower the floating position of the plurality of micro LEDs, thereby guiding some of the plurality of micro LEDs into the plurality of apertures of the mask; and (c1) attaching, to the target substrate, some of the micro LEDs guided into the apertures.

### TECHNICAL FIELD

The present disclosure relates to a method for manufacturing a micro light-emitting diode (LED) display and, more specifically, to a method for assembling multiple micro LEDs into a display panel in a high yield.

### BACKGROUND ART

Recently, in accordance with the increasing demand for development of information devices using flat panel displays, there is a growing need for developing displays with excellent performance in various environments.

Currently, commercialized flat display technologies consist of liquid crystal displays (LCDs) and organic light-emitting diodes (OLEDs). However, the LCD display is limited in brightness and faces challenges in flexible implementation due to the reliance thereof on backlighting and color filters, and the OLED display encounters issues like high costs and low yield rates resulting from the vacuum deposition process, as well as a shorter lifespan.

Micro LEDs refer to ultra-small light-emitting devices having a size of 100 μm or less, and correspond to a semiconductor component that converts an applied voltage into light and has various advantages such as low power consumption, the capability to achieve high brightness of over 10,000 nits, and high durability leading to extended lifespan.

In order to implement a display using such a small-sized semiconductor device, a technology for stably transferring a large amount of micro LEDs to a display panel is required.

Mini LEDs larger than micro LEDs use a pick & place technology, but the small size of micro LEDs makes them difficult to handle with traditional pick-and-place heads, leading to extended transfer times and substantial increases in manufacturing costs. In addition, a method for first transferring chips from a wafer on which LEDs are grown using a polymer-based elastomer pad and then finally transferring same to a panel has been developed, but there is a limited to an area which may be transferred at one time and the life span of the elastomer pad is short, thus causing problems that the transfer reliability is low, the process cost is high, and it is difficult to repair when a defect occurs.

### DISCLOSURE OF INVENTION

### Technical Problem

In order to address the issues of conventional technologies as described above, an aspect of the present disclosure is to provide a method for assembling a micro LED display by stably transferring a large number of micro LEDs onto a substrate.

Furthermore, an aspect of the present disclosure is to provide a method for assembling a micro LED display, which is capable of transferring a large amount of micro LEDs to a substrate at once by floating the micro LEDs in a fluid.

Furthermore, an aspect of the present disclosure is to provide a method for assembling a micro LED display, which is capable of accurately transferring a large amount of LEDs floating in a fluid to a preset mounting position on a substrate.

Furthermore, an aspect of the present disclosure is to provide a method for assembling a micro LED display, which is capable of accurately transferring a large amount of micro LEDs floating in a fluid to a preset mounting position on a substrate by adjusting a level of the fluid.

Furthermore, an aspect of the present disclosure is to provide a method for assembling or repairing a micro LED display, which is capable of accurately transferring a portion of micro LEDs to a micro LED defect position on a substrate after floating a large amount of micro LEDs in a fluid.

Furthermore, an aspect of the present disclosure is to provide a method for assembling or repairing a micro LED display, which is also applicable to an intermediate stage transfer substrate for transfer to a micro LED display.

### Solution to Problem

In order to achieve the technical tasks described above, the present disclosure provides a method for attaching micro LEDs at preset mounting positions on a target substrate, the method including: an operation a1 of disposing, at the bottom of a filled fluid, a target substrate assembly to which micro LEDs are to be attached, and preparing a water tank in which the multiple micro LEDs float in the fluid or on the surface of the fluid on the target substrate assembly, the target substrate assembly including a target substrate and a mask, which is stacked on the surface of the target substrate and has multiple apertures that open positions corresponding to the preset mounting positions at which the micro LEDs are to be attached; an operation b1 of lowering the level of the fluid in the water tank so as to lower the floating position of the multiple micro LEDs, thereby guiding a portion of the multiple micro LEDs into the multiple apertures of the mask; and an operation c1 of attaching, to the target substrate, the portion of the micro LEDs guided into the apertures.

The present disclosure may further include, after the operation c1, an operation d1 of raising a level of the fluid in the water tank in the attached state of the micro LED. In this case, the method may further include operation e1 of separating the target substrate assembly from the water tank in the attached state of the micro LED.

In addition, the present disclosure may further include, after the operation c1, an operation f1 of separating the target substrate assembly from the water tank in the attached state of the portion of the micro LEDs.

In the present disclosure, the fluid may include at least one selected from the group consisting of water, alcohol, and acetone.

The fluid in the present disclosure may include water and may further include an additive to control the surface tension of water.

Furthermore, in the present disclosure, the fluid may include a first fluid and a second fluid having different specific gravities, the first fluid may include water, and the second fluid may include a fluid having a surface tension of less than 0.071 N/m at 25° C. and having a specific gravity of less than 1.

In addition, the micro LED in the present disclosure may include a hydrophobic coating on a portion of a surface thereof.

In the operation c1 in the present disclosure, micro LEDs may be attached to the target substrate by an electric field or a magnetic field.

The mask in the present disclosure may include an aperture for guiding the micro LEDs, corresponding to the preset mounting positions and an electrode structure for generating an electric field or a magnetic field.

In the present disclosure, the aperture of the mask may include an inclined lateral wall having a hole diameter decreasing downwardly or a stepped lateral wall having a hole diameter decreasing downwardly.

In the present disclosure, the target substrate may include an electrode structure for generating an electric field or a magnetic field in order to attach, to the target substrate, the portion of the micro LEDs guided into the aperture.

In addition, in the present disclosure, the mask may include a stacked structure including a first mask unit including an array of first through-holes for guiding the micro LEDs corresponding to the preset mounting positions, and a second mask unit including a second through-hole aligned with the first through-hole and an electrode structure for generating an electric field or a magnetic field around the second through-hole.

In order to address the other technical tasks described above, the present disclosure provides a method for attaching micro LEDs at preset mounting positions on a display substrate, the method including: an operation a2 of disposing, at the bottom of a filled fluid, a transfer substrate assembly to which micro LEDs are to be attached, and preparing a water tank in which the multiple micro LEDs float in the fluid or on the surface of the fluid on the transfer substrate assembly, the transfer substrate assembly including a first transfer substrate and a mask, which is stacked on the surface of the first transfer substrate and has multiple apertures that open positions corresponding to the preset mounting positions on the transfer substrate, at which the micro LEDs are to be attached; an operation b2 of lowering the level of the fluid in the water tank so as to lower the floating position of the multiple micro LEDs, thereby guiding a portion of the multiple micro LEDs into the multiple apertures of the mask; an operation c2 of attaching, to the first transfer substrate, the portion of the micro LEDs guided into the apertures; an operation d2 of removing the mask in a state in which the micro LEDs are attached to the first transfer substrate; and an operation e2 of transferring the micro LEDs on the first transfer substrate to the display substrate.

In the operation c2 of the present disclosure, the first transfer substrate may include a first electrode structure disposed at a position corresponding to the apertures of the mask, and the micro LEDs may be attached to the first transfer substrate by an electric field or a magnetic field applied by the first electrode structure.

In addition, the operation e2 may include an operation e21 of transferring the micro LEDs on the first transfer substrate to a second transfer substrate; and an operation e22 of transferring the micro LEDs on the second transfer substrate to the display substrate.

In addition, in the operation e21, the second transfer substrate may include a second electrode structure corresponding to the first electrode structure of the first transfer substrate, and the micro LEDs may be transferred to the second transfer substrate by an electric field or a magnetic field applied by the second electrode structure.

In order to achieve still other technical tasks described above, the present disclosure provides a method for attaching micro LEDs at preset mounting positions on a target substrate, the method including: an operation a3 of disposing, at the bottom of a filled fluid, a target substrate assembly to which micro LEDs are to be attached, and preparing a water tank in which the multiple micro LEDs float in the fluid or on the surface of the fluid on the target substrate assembly, the target substrate assembly including a target substrate and a mask, which is stacked on the surface of the target substrate and has multiple apertures that open positions corresponding to the preset mounting positions at which the micro LEDs are to be attached, and a portion of the preset mounting positions on the target substrate being deficient in micro LEDs; an operation b3 of lowering the level of the fluid in the water tank so as to lower the floating position of the multiple micro LEDs, thereby guiding a portion of the multiple micro LEDs into the multiple apertures of the mask; and an operation c3 of selectively attaching the portion of the micro LEDs guided into the apertures to the mounting position deficient in micro LEDs from among the preset mounting positions of the target substrate.

In the operation c3 of the present disclosure, an electric field or a magnetic field may be selectively applied to the mounting positions deficient in micro LEDs among the preset mounting positions of the target substrate.

### Advantageous Effects of Invention

The present disclosure may provide a method for assembling an LED display, which may transfer a large amount of LEDs to a substrate stably.

Furthermore, according to the present disclosure, a large amount of micro LEDs may be floated in a fluid and transferred collectively to preset mounting positions on a substrate.

Furthermore, the present disclosure may provide a method for assembling or repairing a micro LED display, which is capable of repair by accurately transferring some of micro LEDs to a micro LED defect position on a substrate after floating a large amount of micro LEDs in a fluid.

Furthermore, the assembling method of the present disclosure is also applicable to an intermediate stage transfer substrate for transfer to a micro LED display.

### BRIEF DESCRIPTION OF DRAWINGS

FIG. 1A is a view schematically illustrating a portion of cross-sectional structure of a display device.

FIG. 1B is a view schematically illustrating an example of a pixel array of a display device.

FIGS. 2A to 2G are views schematically illustrating a method for assembling a micro LED display according to an embodiment of the present disclosure.

FIG. 3 is a view illustrating an example of a micro LED.

FIG. 4 is an enlarged view illustrating a target assembly substrate described in the assembling method of FIG. 3.

FIG. 5 is a schematic view illustrating various shapes of a mask aperture according to an embodiment of the present disclosure.

FIG. 6 is a view schematically illustrating another example of a mask in an embodiment of the present disclosure.

FIGS. 7A to 7F are views schematically illustrating a method for assembling a micro LED display according to another embodiment of the present disclosure.

FIG. 8 is a view schematically illustrating a cross-section of a target substrate assembly used for a procedure of an embodiment of the present disclosure.

FIGS. 9A to 9H are views schematically illustrating a method for assembling a micro LED display according to still another embodiment of the present disclosure.

FIGS. 10A to 10D are views illustrating a repair method in case of micro LED deficiency of a certain mounting position among mounting positions on a target substrate.

### BEST MODE FOR CARRYING OUT THE INVENTION

Hereinafter, the present disclosure will be described in detail by explaining preferred embodiments of the present disclosure with reference to the drawings.

A micro light-emitting diode (LED) in the specification of the disclosure refers to an LED element having an area of 100 μm*100 μm or less or a horizontal and vertical size of 100 μm or less, respectively.

In the specification of the present disclosure, the display device includes an integral display displaying information based on LED elements, may correspond to a wearable display used in TVs, signage, smart phones, laptop computers, automobile HUDs, laptop BLUs, tablets, smart watches, virtual reality (VR) devices, augmented reality (AR) device, and the like, and may also refer to parts or semi-finished products such as display panels, without limitation to finished products.

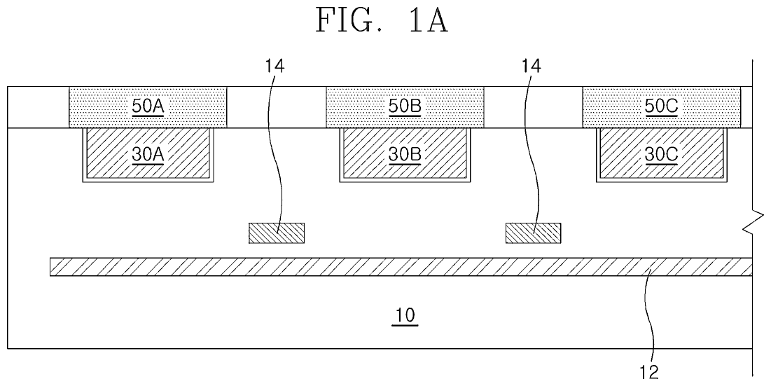

FIG. 1A is a view schematically illustrating a portion of cross-sectional structure of a display device.

As shown in the drawing, the display device includes a substrate 10, a first electrode 12, a second electrode 14, and a semiconductor light-emitting element 30A, 30B, or 30C.

The substrate 10 may correspond to a flexible substrate. For example, the substrate may include glass or polyimide (PI) for realizing a flexible display device. In addition, any material that satisfies insulation and flexibility, for example, polyethylene naphthalate (PEN), polyethylene terephthalate (PET), and the like may be used.

A predetermined region on a plane including each of the semiconductor light-emitting elements 30A, 30B, and 30C may be defined as sub-pixels corresponding to red (R), green (G), and blue (B). The sub-pixels are repeated across the entire screen of the display device to configure a pixel array.

In the present disclosure, a color conversion layer 50A, 50B, or 50C may be selectively added to a light output side of the light-emitting element 30A, 30B, or 30C. For example, when the semiconductor light-emitting element 30A, 30B, or 30C corresponds to a light-emitting element emitting blue light, a color conversion layer 50A may be a phosphor that emits red light when excited by an emission wavelength of a blue light-emitting element, and a color conversion layer 50B may be a phosphor that emits green light when excited by the emission wavelength of the blue light-emitting element. Here, a color conversion layer 50C may be realized with a predetermined light-transmitting material that transmits light of the blue light-emitting element. Although a phosphor have been exemplified as the color conversion layer, the present disclosure is not limited thereto. For example, a quantum-dot color conversion layer may certainly be used as the color conversion layer. In addition, although the case in which the color conversion layer is provided on the light output side of the light-emitting element has been described, the present disclosure is not limited thereto. For example, the light-emitting elements may certainly be realized by LED elements emitting light of different wavelengths, such as R, G, and B, respectively

In the present disclosure, each of the semiconductor light-emitting elements 30A, 30B, and 30C may be individually controlled. To this end, a first electrode 12 and a second electrode 14 for driving the semiconductor light-emitting elements 30A, 30B, and 30C may be wired to the substrate 10. An electrode terminal for electrical connection between a device electrode of the semiconductor light-emitting element and the first and second electrodes may be provided in a seating space in which the semiconductor light-emitting elements 30A, 30B, and 30C are seated.

In addition, in the display device of the present disclosure, each pixel may further include an empty repair area to add a semiconductor light-emitting element of a corresponding color when a defect occurs in a sub-pixel.

FIG. 1B is a view schematically illustrating an example of a pixel array of a display device.

Referring to FIG. 1B, one pixel on the plane of the display device includes three R, G, and B sub-pixels and a repair sub-pixel each defined in a square grid, and pixels configure a two-dimensional array on the plane of the display device.

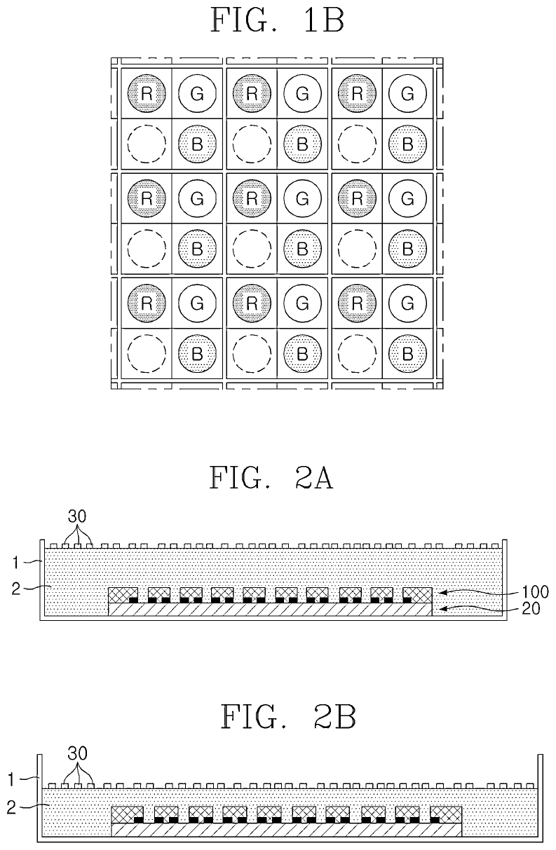

FIGS. 2A to 2G are views schematically illustrating a method for assembling a micro LED display according to an embodiment of the present disclosure.

First, referring to FIG. 2A, a water tank 1 filled with a fluid 2 is prepared. Multiple micro LEDs 30 are dispersed inside the fluid or on a surface of the fluid. A target substrate 20 is disposed inside the fluid of the water tank 1.

The target substrate 20 of the embodiment may correspond to the display substrate 10 described with reference to FIG. 1. Alternatively, the target substrate 20 may correspond to a transfer substrate for transfer to the display substrate 10.

Although it is described that the target substrate is disposed at the lowest portion of the fluid, that is, near the bottom of the water tank in the drawing, the present disclosure is not limited thereto, and the target substrate may certainly be disposed at an appropriate position of a lower part of the micro LED.

A mask 100 is stacked on the target substrate 20. In the present disclosure, it is desirable that an assembly of the target substrate and the mask (hereinafter referred to as “target substrate assembly”) is stacked so as to be separable from each other.

The mask includes apertures corresponding to mounting positions of the light-emitting elements of the target substrate. In case that the target substrate is a display substrate, the mask includes apertures for opening positions corresponding to the seating space for mounting the light-emitting element of FIG. 1.

Meanwhile, a layer in which the micro LEDs are intensively dispersed may be generated on the surface of the fluid in the water tank or on a lower portion near the surface thereof by the buoyancy of the fluid and the interfacial tension between the fluid and the micro LED. The floating layer may be generated at a location spaced a predetermined distance apart from the target substrate. In the present disclosure, the formation position of the floating layer may be determined according to the specific gravity of the used fluid, the micro LED and/or the interfacial tension between the fluid and the micro LED, or the like.

In the present disclosure, the multiple micro LEDs dispersed in the floating layer may generate substantially one mono-layer, but is not limited thereto, and the floating layer may have a multi-layer (multi-layer) structure in which the multiple micro LEDS are arranged in two or more layers. In the present disclosure, it is desirable for the adjacent micro LEDs in the floating layer to be dispersed with appropriate spacing.

In the present disclosure, dispersion density of the micro LEDs dispersed in the floating layer may be defined as an average number of micro LEDs present in a reference area when viewing the floating layer from the top of the tank, and the reference area of the floating layer may be defined as a size of the sub-pixel.

In this case, a case that the dispersion density of the micro LED is 1 indicates a case that one micro LED is dispersed on average in the planar area of the floating layer corresponding to the size of the sub-pixel. In the present disclosure, it is desirable that the dispersion density of the micro LED is 1 or more. In addition, an upper limit of the dispersion density of the micro LED may be appropriately configured depending on the display device. For example, the dispersion density may have a value of 1.5 or less, 2 or less, 3 or less, 5 or less, 10 or less, 50 or less, or 100 or less. In the present disclosure, the dispersion density of the micro LED may depend on the size of the micro LED. For example, the dispersion density may have a greater value as the size of the micro LED decreases.

In the present disclosure, it is desirable that the fluid is in a liquid state, and the fluid may include a liquid such as water, alcohol, and acetone, or a mixture thereof. Desirably, the fluid may include water. In addition, the fluid may include an additive for controlling (decreasing or increasing) the surface tension of the liquid. For example, water is approximately 0.072 N/m at 25° C., but the surface tension at 25° C. may be controlled to have a value of 0.071 to 0.072 N/m by including an additive (surfactant) that reduces the surface tension. For example, additives such as decyl glucoside and lauramidopropyl betaine (LMPB) may be used.

In addition, in the present disclosure, the fluid may correspond to a multilayer fluid including two or more liquids that do not mix with each other. For example, a double-layer fluid in which a second fluid (e.g., oil) having a specific gravity of less than 1 is mixed with a first fluid (e.g., water) may be used. Here, it is desirable that the second fluid has a surface tension smaller than that of water, which is the first fluid, at 25° C., and, for example, the second fluid may have a surface tension of less than 0.071 N/m, less than 0.070 N/m, or less than 0.065 N/m.

In this case, the multiple micro LEDs may configure a floating layer at an interface of the multi-layer fluid.

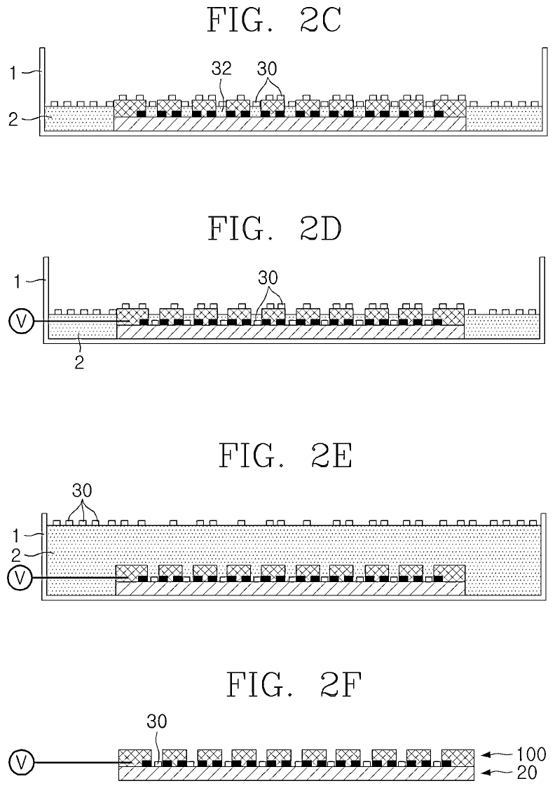

FIG. 3 is a view illustrating an example of a micro LED.

Referring to FIG. 3, the micro LED 30 includes a first surface 32A, which is a mounting surface to a substrate, and a second surface 32B facing the first surface 32A. Device electrodes 34 and 36, which are an electrical contact for driving the micro LED, are disposed on the first surface 32A of the micro LED. Although FIG. 3 illustrates that the device electrodes 34 and 36 are disposed on the first surface, which is the mounting surface, the present disclosure is not limited thereto, and the electrodes may be disposed on the second surface, which is the opposite surface.

In the present disclosure, it is desirable that the dispersed micro LEDs have specific surfaces oriented in the same direction. In the present disclosure, various methods may be used for orientation of the micro LED. For example, by disposing a hydrophobic coating on the second surface 36 of the micro LED, the first surface 34, which is the mounting surface, may spontaneously oriented to face the substrate when the micro LED comes into contact with water. Here, the hydrophobic coating may be disposed on a portion or the entirety of the second surface 36. The disposed hydrophobic coating may be removed at an appropriate time point in an assembly process. By way of example, the hydrophobic coating may be removed after the micro LED is soldered to the target substrate.

Next, referring to FIGS. 2B to 2D, a process of guiding the dispersed micro LEDs to the target substrate 20 will be described.

First, referring to FIG. 2B, the micro LED is guided into the target substrate 20 by decreasing a separation distance between the target substrate and the micro LED. The separation distance between the target substrate and the micro LED may be reduced by a method of lowering a level of the fluid. The method may be realized by configuring a fluid drain structure at a lower portion of the water tank. It may certainly be possible to reduce the distance between the target substrate and the floating layer by moving the target substrate in the direction of the floating layer alternatively or simultaneously. Except for reduction in distance between the floating layer and the target substrate in the process of FIG. 2B, it is desirable for the micro LEDs in the water tank to maintain a dispersed state within the floating layer as much as possible.

Thereafter, when the level of the fluid is lowered further and decreases below the mask 100, as shown in FIG. 2C, some micro LEDs in the fluidized bed are captured into the apertures of the mask, while others are captured in the mask. As such, the mask may selectively guide the micro LEDs to the apertures according to positions where the micro LEDs are disposed in the fluidized bed.

To this end, a size of a passage cross section of an aperture of the mask may be appropriately configured. In the present disclosure, the passage cross-section of the aperture of the mask indicates a cross-section having a smallest size among cross-sections of the apertures at an predetermined point in a direction in which a micro LED falls.

The cross section of the apertures may change depending on a position of the aperture, and in order for the micro LED to pass therethrough, a size (or area) of a minimum cross section of the aperture is required to be greater than a size (or area) of a cross section of the micro LED. In the specification of the present disclosure, the cross-section of the micro LED indicates a cross-section having a largest size (or area) among LED cross-sections in any direction, and exemplarily, as shown in FIG. 3, the cross-section of the micro Led may correspond to a cross-section obtained by cutting an edge of the micro LED diagonally.

A cross-sectional area of the passage cross-section of the aperture of the mask is desirable to be greater than 1, 1.1, 1.2, 1.3, or 1.4 times a cross-sectional area of the micro LED. In addition, in the present disclosure, it is desirable that the pass cross sectional area defined by the aperture of the mask is 1.5 times or less, 1.6 times or less, 1.7 times or less, 1.8 times or less, 2 times or less, 3 times or less, or 4 times or less than the cross-sectional area of the micro LED.

Next, referring to FIG. 2D, the micro LED captured in the aperture is attached to the target substrate. This process may be performed by providing an attractive force to attract the micro LED to the target substrate. The attractive force may be based on an electric, magnetic, or electromagnetic field applied around the micro LED. A phenomenon called dielectrophoresis (DEP), where a material possessing permanent or induced dipoles experience a force along a gradient of an electric field under a non-uniform electric field condition, is an example of an attractive force.

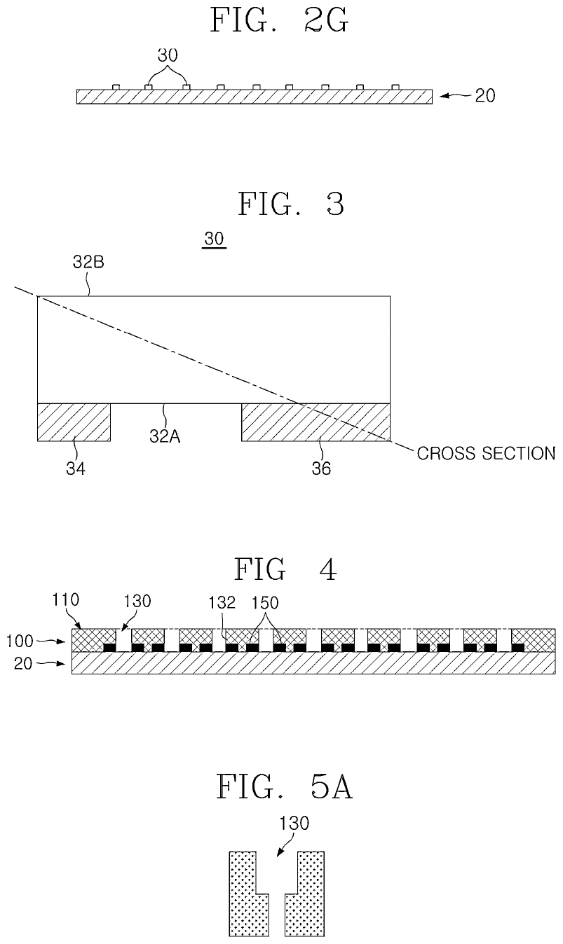

FIG. 4 is an enlarged view illustrating a target assembly substrate described in the assembling method of FIG. 3.

Referring to FIG. 4, the mask 100 is stacked on top of the target substrate 20. The mask include a mask body 110 and an aperture 130. The aperture 130 of the mask opens a predetermined area of the target substrate. For example, when the target substrate is the display substrate described with reference to FIG. 1A, the aperture opens a mounting position of the micro LED 30 of the sub-pixel. Although only a one-dimensional arrangement of the apertures is illustrated in the drawing, a person skilled in the art would know that the apertures 130 configure a two-dimensional array so as to correspond to sub-pixels in the present disclosure.

In the present disclosure, the mask 100 includes an electrode 150 to provide an attractive force for attaching the captured micro LED to the target substrate. A disposition position of the electrode may be appropriately selected. For example, the electrode 150 may be disposed on a lower end of the aperture in the mask.

Although not separately described, an electric wire for applying power to the electrode 150 may be provided in the mask.

Although it is described that an aperture lateral wall 132 configuring the aperture 130 is disposed at a right angle with respect to the target substrate in FIG. 4, the present disclosure is not limited thereto. For example, the aperture lateral wall 132 may be inclined with respect to the target substrate. By way of example, the aperture cross-section of the aperture may be designed to gradually decrease as the micro LED is closer to the target substrate so that the micro LED is smoothly guided into the target substrate.

The aperture 130 may have a cylindrical or polyhedral cross-sectional shape to allow the micro LED to pass therethrough. It is recommended that when the micro LED has a cylindrical shape, the aperture is configured to have a cylindrical or square column shape, and when the micro LED has a polyhedral shape, the aperture is configured to have a cylindrical shape.

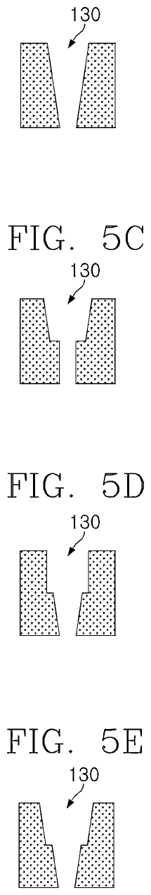

Meanwhile, the aperture of the mask usable in the present disclosure may have a stepped structure. FIG. 5 is a schematic view illustrating various shapes of a mask aperture.

As described in the drawing, the aperture of the mask may be configured to have one or more stages so that a micro LED chip entering the aperture 130 may filtered, and each stage may be configured to has a cylindrical shape or a square column shape or a cone shape or a square pyramid shape that narrows downward.

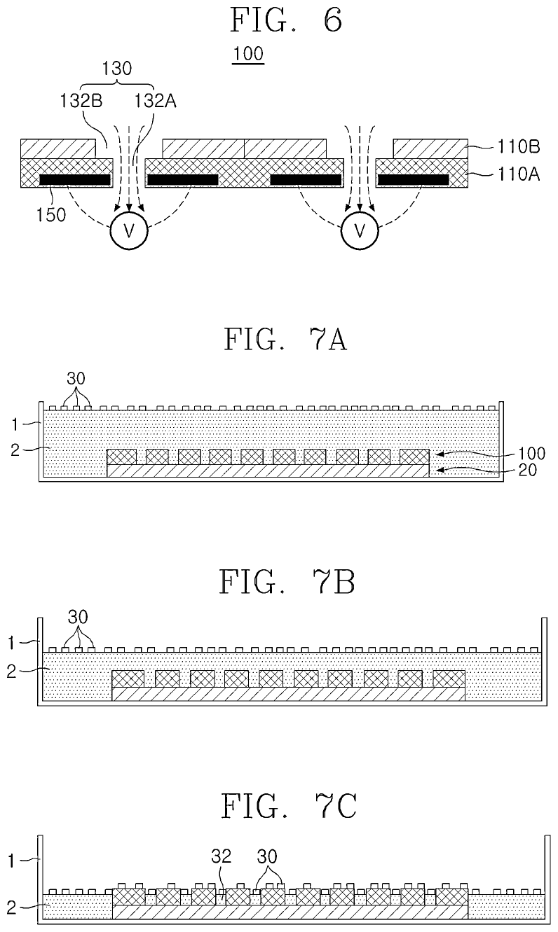

FIG. 6 is a view schematically illustrating another example of a mask 100 the present disclosure.

Referring to FIG. 6, the mask 100 includes a stacked structure of a first mask unit 110A and a second mask unit 110B.

The first mask unit 110A includes a first through-hole 132A array and the second mask unit 110B includes a second through-hole 132B array. As shown above, a diameter of the first through-hole 132A is greater than that of the second through-hole 132B. In addition, the first through-hole 132A array and the second through-hole 132B array are aligned with each other to define the aperture 130. The staked structure thereof allows the mask aperture to have stepped lateral walls in which the hole diameter decreases toward the bottom.

On the other hand, the electrode 150 providing adhesion between the micro LED and the target substrate is disposed on the lower portion of the first mask unit 110A that comes into contact with the target substrate, and by applying an AC voltage, an attractive force is applied between the micro LED and the substrate by an electric field or a magnetic field.

Referring to FIGS. 2E and 2F again, additional operations of the micro LED assembly method of the present disclosure will be described.

First, FIG. 2E shows an example of a method of removing a micro LED hanging on an upper portion of the mask without being captured by the aperture of the mask. That is, a non-captured micro LED 130 may be separated from the mask by raising the level of the fluid in the water tank. Here, a voltage is applied to an attachment electrode of the mask to keep the micro LED captured in the aperture of the mask attached to the target substrate.

The removal method of FIG. 2E is merely an example, and the present disclosure is not limited thereto, and various methods such as washing may certainly be used.

Subsequently, as shown in FIG. 2F, the target substrate assembly to which the micro LED is attached is separated from the water tank. Here, a voltage is applied to an attachment electrode of the mask to keep the micro LED captured in the aperture of the mask attached to the target substrate. Various methods may be applied to separate the target substrate from the water tank. For example, the substrate assembly may be discharged through a discharge port equipped with an opening and closing shutter installed in the water tank.

Subsequent processes are performed on the target substrate separated through the above process. In case that the target substrate corresponds to a display substrate, as shown in FIG. 2F, the micro LED attached to the target substrate may be electrically coupled to the target substrate through a process such as soldering. When the soldering is completed, the target substrate and the mask are separated and the assembly process is completed.

### Mode for Carrying Out the Invention

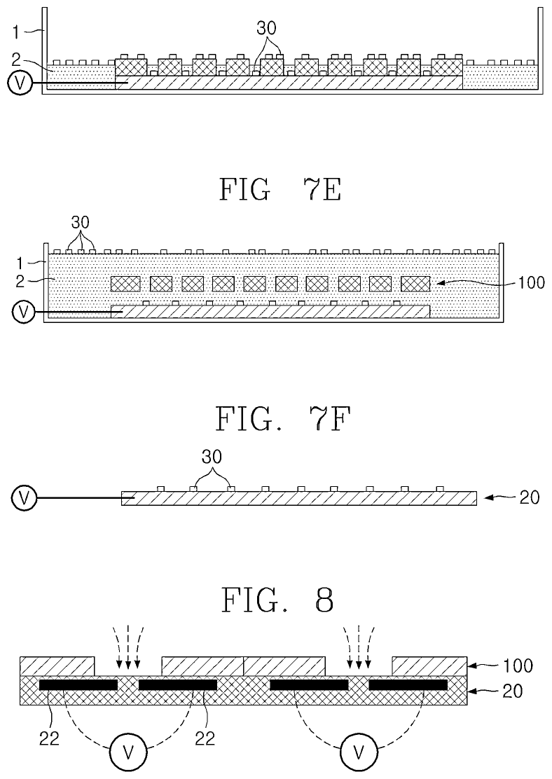

FIGS. 7A to 7F are views schematically illustrating a method for assembling a micro LED display according to another embodiment of the present disclosure.

Referring to the drawings, a procedure of FIGS. 7A to 7C is identical to that described in FIGS. 2A to 2C.

As shown in FIGS. 7D and 7E, an electrode disposed on the target substrate is used to attach the captured micro LED 30 on the target substrate in the present disclosure. In this case, the mask may be removed immediately after the micro LED 30 is attached. The mask is separated from the target substrate after the micro LED hanging on the upper portion of the mask is removed by raising the level of the fluid in the water tank. Thereafter, in a state in which a voltage is applied to the attachment electrode of the target substrate, the mask may be separated from the water bath as shown in FIG. 7F.

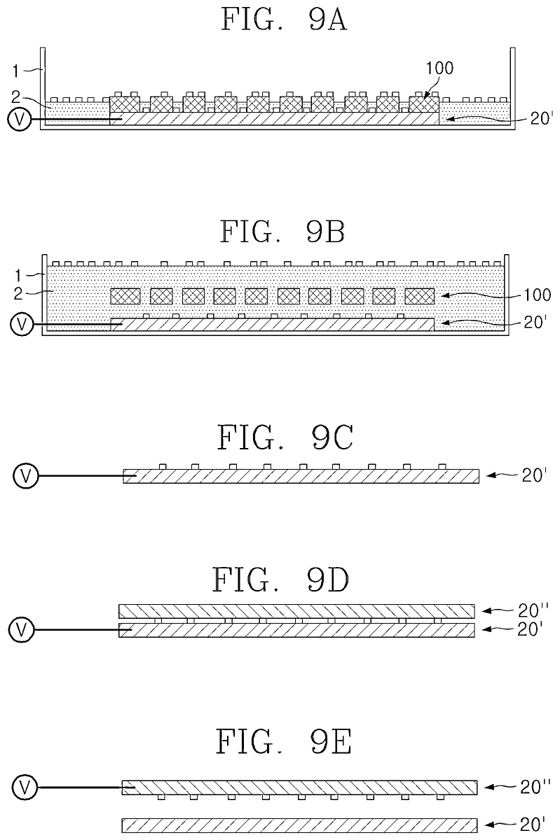

FIG. 8 is a view schematically illustrating a cross-section of the target substrate assembly used for the procedure described in FIG. 7. As shown in the drawing, a voltage is applied to a substrate electrode 22 disposed on the target substrate 20 rather than the mask 100 and the micro LED is attached to the target substrate 20.

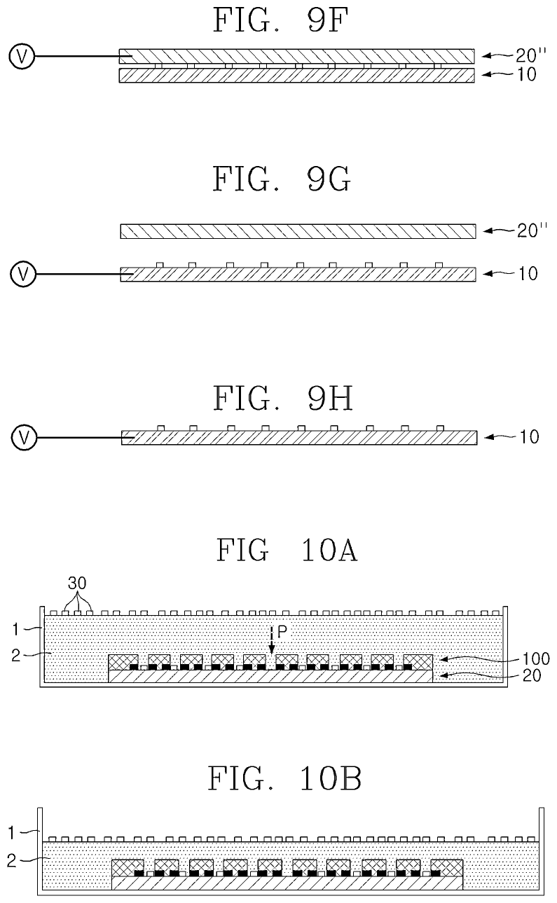

FIGS. 9A to 9H are views schematically illustrating a method for assembling a micro LED display according to still another embodiment of the present disclosure. Unlike the previous embodiments, in this embodiment, a temporary transfer substrate is used as a target substrate.

Through a process similar to that described in FIGS. 7A to 7D, the captured micro LED as shown in FIG. 9A is attached by a voltage applied to an electrode of a first transfer substrate 20′.

Thereafter, as shown in FIG. 9B, the micro LED hanging on the upper portion of the mask 100 is removed by raising the level of the fluid in the water tank, and the mask is separated from the first transfer substrate. Subsequently, the first transfer substrate may be separated from the water tank as shown in FIG. 9C in a state in which a voltage is applied to the attachment electrode of the first transfer substrate.

Thereafter, a transfer process from the first transfer substrate 20′ to a second transfer substrate 20″ (FIGS. 9D and 9E), and a transfer process from the second transfer substrate 20″ to the display substrate 10 (FIGS. 9F to 9H) are performed. In the processes, driving of the attachment electrodes on the first transfer substrate 20′, the second transfer substrate 20″, and the display substrate 10 is as shown in the drawings.

Meanwhile, the above embodiment is performed based on the assumption that the element electrode of the micro LED floating in the fluid is oriented to face the first transfer substrate, and a person skilled in the art would understand that it is possible to use only one transfer substrate when the element electrode of the micro LED is oriented in the opposite direction.

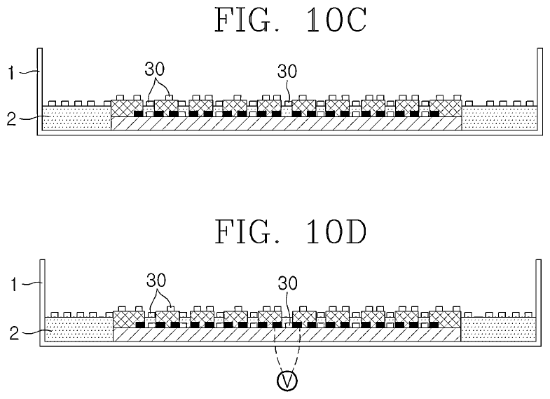

Hereinafter, a repair method in case of micro LED deficiency of a certain mounting position among mounting positions on a target substrate will be described with reference to FIGS. 10A to 10D.

As shown in FIG. 10A, the target substrate assembly in which a micro LED is deficient at a partial mounting position P is disposed on a lower portion of the water tank, and multiple micro LEDs 30 are floated in the fluid.

As shown in FIGS. 10B and 10C, the micro LEDs are captured in the aperture of the mask by adjusting the level of the fluid.

Thereafter, as shown in FIG. 10D, by selectively applying a voltage to the defective mounting position on the target substrate, a micro LED captured at the defective position is attached to the target substrate. Although it is described that the attachment electrode is disposed on the mask in the drawings, the present disclosure is not limited thereto, and it is also possible to attach the micro LED to the target substrate using an electrode disposed on the target substrate.

Thereafter, by raising the level of the fluid, the micro LED captured in the aperture other than that on the defective mounting position may be floated and removed from the target substrate.

Subsequently, the method described above may be used to separate the target substrate from the water tank, and the micro LED attached to the defective position may be soldered to the target substrate.

The above description is merely an example of the technical ideas of the disclosure, and various modifications and variations will be apparent to those skilled in the art to which the disclosure belongs, without departing from the essential features of the disclosure.

### INDUSTRIAL APPLICABILITY

The present disclosure may be applied to a micro light-emitting diode (LED) display and a manufacturing method thereof.

1. A method for attaching micro LEDs at preset mounting positions on a target substrate, the method comprising:
an operation (a1) of disposing, at a bottom of a filled fluid, a target substrate assembly to which micro LEDs are to be attached, and preparing a water tank in which the multiple micro LEDs float in the fluid or on a surface of the fluid on the target substrate assembly, the target substrate assembly comprising a target substrate and a mask, which is stacked on the surface of the target substrate and has multiple apertures that open positions corresponding to preset mounting positions at which the micro LEDs are to be attached;
an operation (b1) of lowering a level of the fluid in the water tank so as to lower a floating position of the multiple micro LEDs, thereby guiding a portion of the multiple micro LEDs into the multiple apertures of the mask; and
an operation (c1) of attaching, to the target substrate, the portion of the micro LEDs guided into the apertures.

2. The method of claim 1, further comprising, after the operation (c1), an operation (d1) of raising a level of the fluid in the water tank in a state in which the micro LEDs are attached.

3. The method of claim 2, further comprising an operation (e1) of separating the target substrate assembly from the water tank in the state in which the micro LEDs are attached.

4. The method of claim 1, further comprising, after the operation (c1), an operation (f1) of separating the target substrate assembly from the water tank in the attached state of the portion of the micro LEDs.

5. The method of claim 1, wherein the fluid comprises at least one selected from a group consisting of water, alcohol, and acetone.

6. The method of claim 1, wherein the fluid comprises water and an additive to control a surface tension.

7. The method of claim 6, wherein the fluid comprises a first fluid and a second fluid having different specific gravities,
the first fluid comprises water, and
the second fluid comprises a fluid having a surface tension of less than 0.071 N/m at 25° C. and having a specific gravity of less than 1.

8. The method of claim 1, wherein the first fluid comprises water, and
the micro LEDs comprise a hydrophobic coating on a portion of a surface.

9. The method of claim 8, wherein the micro LEDS comprise a first surface to be attached to the target substrate and a second surface opposite to the first surface, and
the hydrophobic coating is disposed on the second surface.

10. The method of claim 9, wherein the first surface comprises an electrode layer.

11. The method of claim 1, wherein in the operation (c1), the micro LEDs are attached to the target substrate by an electric field or a magnetic field.

12. (canceled)

13. The method of claim 1, wherein the mask comprises apertures for guiding the micro LEDs, wherein the apertures of the mask comprise an inclined lateral wall having a hole diameter decreasing downwardly.

14. The method of claim 13, wherein the apertures of the mask comprise a stepped lateral wall having a hole diameter decreasing downwardly.

15. The method of claim 1, wherein the mask comprises apertures for guiding the micro LEDs, which correspond to the preset mounting positions, and
the target substrate comprises an electrode structure for generating an electric field or a magnetic field in order to attach, to the target substrate, the portion of the micro LEDs guided into the apertures.

16. (canceled)

17. The method of claim 1, further comprising an operation (g1) of soldering the attached micro LEDS to the target substrate.

18. A method for attaching micro LEDs at preset mounting positions on a display substrate, the method comprising:
an operation (a2) of disposing, at a bottom of a filled fluid, a transfer substrate assembly to which micro LEDs are to be attached, and preparing a water tank in which the multiple micro LEDs float in the fluid or on a surface of the fluid on the transfer substrate assembly, the transfer substrate assembly comprising a first transfer substrate and a mask, which is stacked on a surface of the first transfer substrate and has multiple apertures that open positions corresponding to preset mounting positions on the transfer substrate, at which the micro LEDs are to be attached;
an operation (b2) of lowering a level of the fluid in the water tank so as to lower a floating position of the multiple micro LEDs, thereby guiding a portion of the multiple micro LEDs into the multiple apertures of the mask;
an operation (c2) of attaching, to the first transfer substrate, the portion of the micro LEDs guided into the apertures;
an operation (d2) of removing the mask in a state in which the micro LEDs are attached to the first transfer substrate; and
an operation (e2) of transferring the micro LEDs on the first transfer substrate to the display substrate.

19. The method of claim 18, wherein in the operation (c2), the first transfer substrate comprises a first electrode structure disposed at a position corresponding to the apertures of the mask, and
the micro LEDs are attached to the first transfer substrate by an electric field or a magnetic field applied by the first electrode structure.

20. The method of claim 18, wherein the operation (e2) comprises:
an operation (e21) of transferring the micro LEDs on the first transfer substrate to a second transfer substrate; and
an operation (e22) of transferring the micro LEDs on the second transfer substrate to the display substrate.

21. The method of claim 20, wherein in the operation (e21), the second transfer substrate comprises a second electrode structure corresponding to the first electrode structure of the first transfer substrate, and
the micro LEDs are transferred to the second transfer substrate by an electric field or a magnetic field applied by the second electrode structure.

22. A method for attaching micro LEDs at preset mounting positions on a target substrate, the method comprising:
an operation (a3) of disposing, at a bottom of a filled fluid, a target substrate assembly to which micro LEDs are to be attached, and preparing a water tank in which the multiple micro LEDs float in the fluid or on a surface of the fluid on the target substrate assembly, the target substrate assembly comprising a target substrate and a mask, which is stacked on a surface of the target substrate and comprises multiple apertures that open positions corresponding to the preset mounting positions at which the micro LEDs are to be attached, and a portion of the preset mounting positions on the target substrate being deficient in micro LEDs;
an operation (b3) of lowering a level of the fluid in the water tank so as to lower a floating position of the multiple micro LEDs, thereby guiding a portion of the multiple micro LEDs into the multiple apertures of the mask; and
an operation (c3) of selectively attaching the portion of the micro LEDs guided into the apertures to a mounting position deficient in micro LEDs from among the preset mounting positions of the target substrate.

23. The method of claim 22, wherein in the operation (c3), an electric field or a magnetic field is selectively applied to the mounting position deficient in micro LEDs among the preset mounting positions of the target substrate.

24. (canceled)

25. The method of claim 22, wherein the mask comprises apertures for guiding the micro LEDs, which correspond to the preset mounting positions, and
the target substrate comprises an electrode structure for generating an electric field or a magnetic field in order to attach, to the target substrate, the portion of the micro LEDs guided into the apertures.
